(19) United States
(12) Patent Application Publication
(10) Pub. No.: US 2007/0049021 A1
(43) Pub. Date: Mar. 1, 2007

(54) ATOMIC LAYER DEPOSITION METHOD

(75) Inventors: Cem Basceri, Reston, VA (US); Gurtej S. Sandhu, Boise, ID (US)

Correspondence Address: WELLS ST. JOHN P.S., 601 W. FIRST AVENUE, SUITE 1300, SPOKANE, WA, 99201, US

(73) Assignee: MICRON TECHNOLOGY, INC.

(21) Appl. No.: 11/216,634

(22) Filed: Aug. 31, 2005

(51) Int. Cl. H01L 21/44

(52) U.S. Cl. 438/680; 257/E21.133

(57) ABSTRACT

The invention includes atomic layer deposition (ALD) methods for forming crystalline materials. The crystalline materials can have a first atomic arrangement within one layer, and a second atomic arrangement within another layer; with the first and second atomic arrangements having different crystallographic orientations relative to one another. Alternatively, or additionally, the crystalline materials can have a first portion with a first concentration of a particular element, and a second portion with a second concentration of the particular element which is different than the first concentration.

### TECHNICAL FIELD

The invention pertains to atomic layer deposition methods. In particular aspects, the invention pertains to methods of forming crystalline dielectric materials for capacitor constructions.

### BACKGROUND OF THE INVENTION

It is frequently desired to form materials in particular crystallographic phases. For instance, so-called perovskite dielectric materials (such as, for example, lead zirconate titanate (PZT), SrTiO₃ (STO), and barium strontium titanate (BST)) can exist in either the perovskite crystalline phase or in a pyrochlore phase. The use of the term “perovskite material” in the art can be somewhat confusing, in that the term refers to compositions that can exist in a perovskite crystalline phase, regardless of whether the compositions are actually in such phase. For purposes of interpreting this disclosure and the claims that follow, the term “perovskite material” will be utilized in its conventional meaning to refer to compositions that can exist in a perovskite crystalline phase and will not imply that the compositions are actually in the perovskite crystalline phase. Thus, it is to be understood that materials referred to herein as be perovskite materials are not necessarily in the perovskite crystalline phase in less it is expressly stated that the materials are in the perovskite crystalline phase.

Perovskite dielectric materials can be utilized in semiconductor constructions, and in such applications it is generally desired that the materials be in the perovskite crystalline phase. An exemplary application for a perovskite dielectric material in a semiconductor construction is as a capacitor dielectric.

Numerous methods have been developed for inducing the perovskite crystalline phase in perovskite dielectric materials, with such methods typically comprising forming a template material which is then utilized to induce the desired phase into the perovskite materials. For instance, SrRuO₃ can be utilized as a template material for BST, and (La, Sr)CoO₃ can be used as a template material for PZT. However, utilization of template materials introduces complexity into the fabrication of desired crystalline perovskite materials, and also reduces the homogeneity of the desired perovskite dielectric materials. Accordingly, it is desired to develop new methods for inducing a desired crystalline phase into perovskite materials. It would be further desirable for such new method to be applicable to other applications in addition to fabrication of perovskite materials.

Various aspects of the invention utilize atomic layer deposition (ALD) processes. ALD processes are generally processes in which precursor materials react at a surface, rather than in a vapor phase above the surface. For instance, an ALD process utilizing two precursors to form a material over a substrate will typically comprise the following sequence. Initially, a first of the two precursors is injected into a reaction chamber having the substrate therein to react with an exposed surface of the substrate and to form a layer on such surface. Any unreacted first precursor, as well as any vapor-phase by-products of the reaction of the first precursor with the surface, are then purged from the reaction chamber so that the first precursor is substantially eliminated from within the reaction chamber. Subsequently, the second precursor is introduced into the chamber to react with a surface that now comprises a component of the first precursor to form a material comprising components from both the first and second precursors. The second precursor can then be substantially entirely purged from within the reaction chamber, and the process repeated with the first precursor, followed by the second precursor, etc. to form a desired material to a desired thickness. The term “substantially eliminated” is utilized to describe the purging of the first and second precursors from within the reaction chamber, and specifically is utilized to indicate that the precursors are removed from the chamber to the extent that there is no detectable vapor phase reaction of the first and second precursors occurring in the chamber during the ALD processing. Thus, the term “substantially eliminated” can encompass applications in which precursors are entirely eliminated from within a reaction chamber, but is not limited to such applications.

As further background regarding ALD technology, such typically involves formation of successive atomic layers on a substrate. The layers may comprise, for example, an epitaxial, polycrystalline, and/or amorphous material. ALD may also be referred to as atomic layer epitaxy, atomic layer processing, etc.

The deposition methods herein are described in the context of formation of materials on one or more semiconductor substrates. In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

Described in summary, ALD includes exposing an initial substrate to a first chemical species to accomplish chemisorption of the species onto the substrate. Theoretically, the chemisorption forms a monolayer that is uniformly one atom or molecule thick on the entire exposed initial substrate. In other words, a saturated monolayer. Practically, as further described below, chemisorption might not occur on all portions of the substrate. Nevertheless, such an imperfect monolayer is still a monolayer in the context of this document. In many applications, merely a substantially saturated monolayer may be suitable. A substantially saturated monolayer is one that will still yield a deposited layer exhibiting the quality and/or properties desired for such layer.

The first species is purged from over the substrate and a second chemical species is provided to chemisorb onto the first monolayer of the first species. The second species is then purged and the steps are repeated with exposure of the second species monolayer to the first species. In some cases, the two monolayers may be of the same species. Also, a third species or more may be successively chemisorbed and purged just as described for the first and second species. It is noted that one or more of the first, second and third species can be mixed with inert gas to speed up pressure saturation within a reaction chamber.

Purging may involve a variety of techniques including, but not limited to, contacting the substrate and/or monolayer with a carrier gas and/or lowering pressure to below the deposition pressure to reduce the concentration of a species contacting the substrate and/or chemisorbed species. Examples of carrier gases include N₂, Ar, He, Ne, Kr, Xe, etc. Purging may instead include contacting the substrate and/or monolayer with any substance that allows chemisorption byproducts to desorb and reduces the concentration of a species preparatory to introducing another species. A suitable amount of purging can be determined experimentally as known to those skilled in the art. Purging time may be successively reduced to a purge time that yields an increase in film growth rate. The increase in film growth rate might be an indication of a change to a non-ALD process regime and may be used to establish a purge time limit.

ALD is often described as a self-limiting process, in that a finite number of sites exist on a substrate to which the first species may form chemical bonds. The second species might only bond to the first species and thus may also be self-limiting. Once all of the finite number of sites on a substrate are bonded with a first species, the first species will often not bond to other of the first species already bonded with the substrate. However, process conditions can be varied in ALD to promote such bonding and render ALD not self-limiting. Accordingly, ALD may also encompass a species forming other than one monolayer at a time by stacking of a species. The various aspects of the present invention described herein are applicable to any circumstance where ALD may be desired. It is further noted that local chemical reactions can occur during ALD (for instance, an incoming reactant molecule can displace a molecule from an existing surface rather than forming a monolayer over the surface). To the extent that such chemical reactions occur, they are generally confined within the uppermost monolayer of a surface.

### SUMMARY OF THE INVENTION

In one aspect, the invention includes an ALD method for forming a crystalline material containing a particular element. A first layer of the crystalline material is formed with a first ALD precursor. The first layer has a first concentration of the particular element defined as the number of atoms per unit area of the particular element in the first layer. After the first layer is formed, a second layer of the crystalline material is formed with a second ALD precursor different from the first ALD precursor. The second layer has a second concentration of the particular element defined as the number of atoms per unit area of the particular element in the second layer. The second concentration is different than the first concentration.

In one aspect, the invention encompasses another ALD method for forming a crystalline material. A first layer of the crystalline material is ALD-formed utilizing first conditions. The first layer has an element contained within a first atomic arrangement having a first crystallographic orientation. After the first layer is formed, a second layer of the crystalline material is ALD-formed utilizing second conditions which are different from the first conditions. The second layer has the element contained within a second atomic arrangement which has a second crystallographic orientation different than the first crystallographic orientation.

In one aspect, the invention includes a method of forming a capacitor construction. A first electrode is formed, and a crystalline dielectric material is formed over the first electrode. The formation of the crystalline dielectric material includes formation of a first layer with a first ALD precursor, and formation of a second layer with a second ALD precursor. The crystalline dielectric material comprises a perovskite thin film substantially entirely in a non-pyrochlore phase, and the formation of the crystalline dielectric material is conducted entirely without utilization of a crystallographic template. A second capacitor electrode is subsequently formed over the crystalline dielectric material, with the second capacitor electrode being capacitively coupled with the first capacitor electrode.

### BRIEF DESCRIPTION OF THE DRAWINGS

Preferred embodiments of the invention are described below with reference to the following accompanying drawings.

FIG. 1 is a diagrammatic, cross-sectional view of a semiconductor wafer fragment at a preliminary processing stage of an exemplary aspect of the present invention.

FIG. 2 is a view of the FIG. 1 fragment shown at a processing stage subsequent to that of FIG. 1.

FIG. 3 is a view of the FIG. 1 fragment shown at a processing stage subsequent to that of FIG. 2.

FIG. 4 is view of the FIG. 1 fragment shown at a processing stage subsequent to that of FIG. 3.

FIG. 5 is a view of the FIG. 1 fragment shown at a processing stage subsequent to that of FIG. 4.

FIG. 6 shows diagrammatic representations of two different crystalline structures which can be formed with exemplary ALD methodologies.

FIG. 7 shows a diagrammatic representation of a crystalline structure comprising a mixture of the two structures shown in FIG. 6.

FIG. 8 shows a diagrammatic representation of a crystalline structure comprising dopant incorporated therein.

FIG. 9 shows a diagrammatic representation of a crystalline structure comprising a pair of different components incorporated therein.

FIG. 10 shows a diagrammatic representation of a crystalline structure comprising three different components incorporated therein.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

In some aspects, the invention includes a recognition that ALD can enable control of the physical properties, including crystallographic properties, of each atomic layer within a material, and includes methods of tailoring the crystallographic state of materials through ALD. Each ALD cycle can deposit a layer in a certain atomic arrangement. The net result of multiple ALD cycles (with one or more precursors) can be to deposit a film having a pre-determined crystalline lattice structure and orientation. In particular aspects, unwanted crystallographic phases of a material can be prevented (such as, for example, the undesired pyrochlore phase formation in a perovskite material) with appropriate utilization of ALD to form the material. Such control of crystallographic phases can be achieved by, for example, controlling stoichiometry of films within a single layer. For instance, the concentration of particular elements within various layers can be modified to adjust crystallographic properties of the layers.

In some applications of the invention, superlattices and artificially-structured thin films can be formed without utilization of complicated template structures. For instance, SrTiO₃/BaTiO₃ and (Sr, Ca)TiO₃/(Ba, Sr)(TiO₃) artificial strained super lattices can be formed and/or replaced with simpler processing utilizing ALD methodology of the present invention. Lattice mismatches for these structures can be tailored in single atomic layers of the structures to develop desired dielectric constants within the structures. Additionally, epitaxial growth of thin films can be accomplished utilizing ALD methodologies in some aspects of the invention.

The invention can also include utilization of ALD methodologies to eliminate the complication of using multiple epitaxial layers, (such as, for example, epitaxial barrier and electrode materials beneath dielectric materials (such as BST)), which are conventionally utilized to promote epitaxial growth of the dielectric materials. For instance, an epitaxial TiAlN barrier and epitaxial platinum electrode are conventionally utilized to obtain epitaxially grown BST thin films. However, in aspects of the present invention the crystallographic properties of the BST thin films are imposed by ALD process conditions rather than by the surface that the BST thin films are grown on. Accordingly, methodology of the present invention can enable formation of BST thin films having desired crystallographic properties over numerous surfaces which would not be feasible to use with conventional processes.

In some aspects, the invention can also be utilized to provide lattice continuity and interfaces through ALD methodologies. This again can eliminate the use of complicated stacks associated with conventional methodologies. For instance, complicated stacks have been utilized in the prior art to induce the desired perovskite crystallographic phase in perovskite materials. Specifically, SrRuO₃ is utilized as a template material for inducing desired crystallographic properties in BST; and (La, Sr) CoO₃ is utilized as a template for inducing desired crystallographic properties in ferroelectric thin films (such as PZT). Elimination of the template materials can simplify processing, reduce interfacial defects within dielectric materials, and modify a stress state within the dielectric materials.

In further aspects of the invention, ALD can be utilized to alter stoichiometry within dielectric materials to tailor desired properties, and in some aspects improve the properties for particular desired device characteristics. This can be particularly useful for multi-component films, such as, for example, BaTiO₃, (Ba, Sr)TiO₃, SrTiO₃, PbTiO₃, Pb(Zr,Ti)O₃, (Pb, La)(Zr, Ti)O₃, Pb(Mg, Nb)O₃, and KNbO₃. Layered oxide films such as SrBi₂Ta₂O₉ and SrBi₂(Ta, Nb)₂O₉ are difficult to deposit with conventional techniques due to complexities within the structures. However, ALD methodologies of the present invention can provide viable options to tailor properties of such films by controlling stoichiometry in each atomic layer within the crystalline materials.

Stoichiometry and other physical properties can also be modified/controlled by providing dopants during ALD processing. ALD can enable the dopants to be placed in precise locations within a material. The dopant concentration and locations of dopants within a film (for example, whether the dopants are at bottom or top interfaces of the film, or in a middle of the film thickness) can be tailored to impose desired properties within and throughout a material formed in accordance with various methodologies of the present invention.

In particular aspects, the invention can be utilized for altering lattice mismatches within a perovskite material (or other material) via appropriate dopants and/or appropriate stoichiometry at various interfaces within the materials, without utilization of interfacial layers (i.e., crystallographic template layers). The invention can thus enable the stress state of perovskite films to be altered in desired directions through ALD processing.

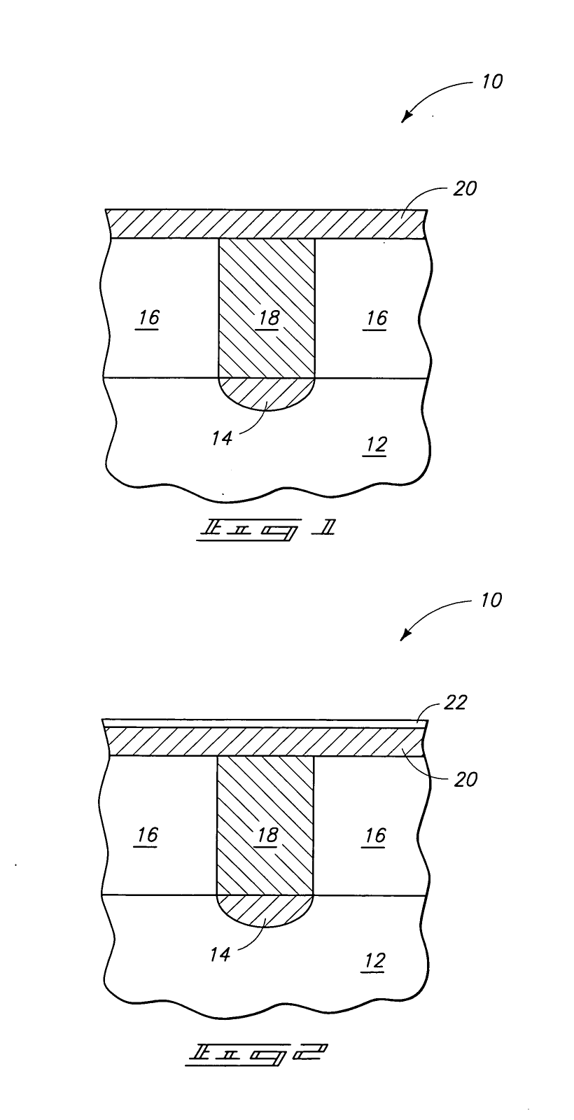

Exemplary aspects of the invention are initially described with reference to FIGS. 1-5.

Referring to FIG. 1, a semiconductor construction 10 is shown at a preliminary processing stage. The construction 10 includes a substrate 12. Such substrate can comprise, consist essentially of, or consist of monocrystalline silicon which, in some aspects, can be lightly background doped with an appropriate dopant.

A conductively-doped diffusion region 14 extends within substrate 12. Diffusion region 14 can be a source/drain region of a transistor device, and accordingly can be proximate a gate (not shown) of such transistor device.

An insulative material 16 is over substrate 12, and a conductive pedestal 18 extends through the insulative material 16 to electrically couple with diffusion region 14. Insulative material 16 can comprise any suitable composition or combination of compositions, and in particular aspects will comprise, consist essentially of, or consist of one or more of borophosphosilicate glass (BPSG), silicon dioxide, spin-on-glass, or phosphosilicate glass (PSG). Conductive pedestal 18 can comprise, consist essentially of, or consist of any suitable electrically conductive composition or combination of compositions, and in particular aspects will comprise various metals, metal compositions, and/or conductively-doped semiconductor material, (such as, for example, conductively-doped silicon). In an exemplary aspect, pedestal 18 can comprise titanium nitride and tungsten.

A first capacitor electrode 20 is over pedestal 18 and electrically coupled with the pedestal 18. Electrode 20 can comprise any suitable electrically conductive composition or combination of compositions, and in particular aspects will comprise metal and/or one or more metal-containing compositions. For instance, electrode 20 can, in particular aspects, comprise, consist essentially of, or consist of platinum or other noble metals, and can be an electrode configured for incorporation into a metal-insulator-metal capacitor.

Referring to FIG. 2, a layer 22 of crystalline dielectric material is formed over electrode 20. Layer 22 is formed with ALD utilizing appropriate conditions to induce a pre-determined atomic arrangement within the layer, and in particular aspects the conditions can be chosen to be appropriate to induce desired crystallographic properties within the layer. Layer 22 can, for example, correspond to a portion of a perovskite dielectric material, such as, for example, BST or PZT.

In some aspects, layer 22 can be formed with a first ALD precursor containing a particular element. The element can be provided to a first concentration within the layer, with such concentration being defined as the number of atoms per unit area of the particular element in the first layer. The particular element can, for example, be selected from the group consisting of barium, bismuth, cobalt, lanthanum, lead, magnesium, niobium, oxygen, ruthenium, strontium, titanium, tantalum and zirconium. The particular element can be in elemental form within layer 22, or can be part of a compound within the layer. In some exemplary aspects, layer 22 will be part of a crystalline dielectric material that is ultimately to be BST, and the particular element will be barium, oxygen, strontium or titanium. In other exemplary aspects, layer 22 will be part of a layer that is ultimately to be PZT, and the particular element will be lead, oxygen, zirconium, or titanium. The particular element within layer 22 is contained within a first atomic arrangement having a first crystallographic orientation.

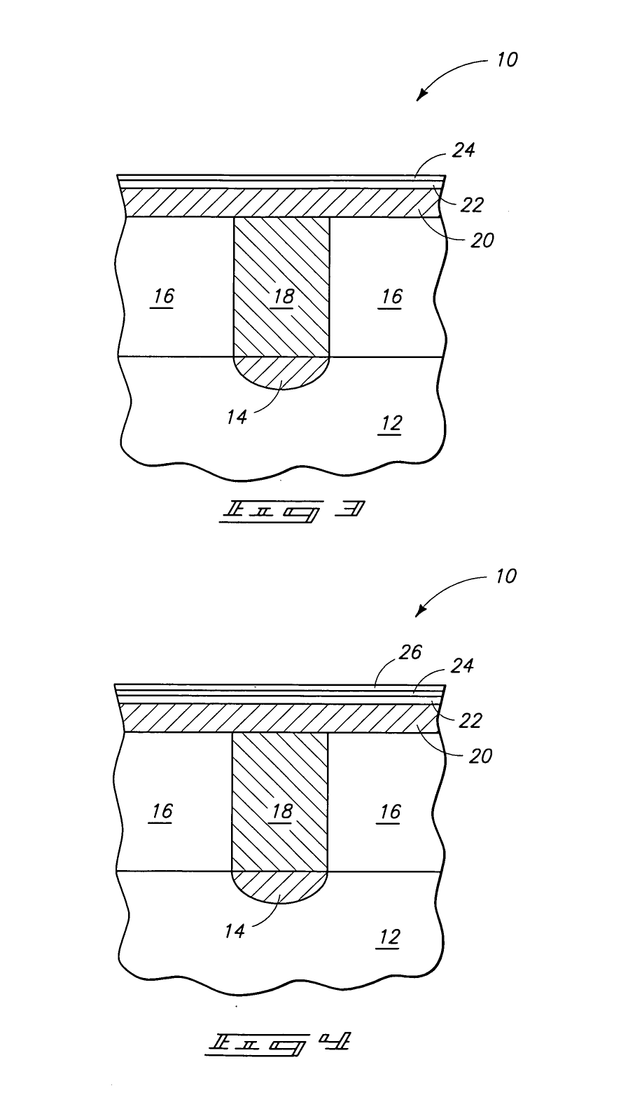

Referring next to FIG. 3, a second layer 24 of the crystalline dielectric material is formed over the first layer 22 of the crystalline dielectric material. The second layer 24 can comprise the same element as the particular element that had been within crystalline layer 22, or not. Layer 24 is formed by ALD processing after the ALD formation of layer 22. In other words, precursor utilized to form layer 22 would be substantially entirely flushed from within a reaction chamber prior to formation of layer 24.

In some aspects, layers 22 and 24 can be together incorporated into BST, and one of the layers can comprise a component of the BST (such as, for example, barium, oxygen, strontium or titanium) while the other layer comprises a different component of the BST. Similarly, the layers 22 and 24 can be part of a PZT material, with one of the layers comprising a component of the PZT different than the other layer.

In some aspects, layers 22 and 24 can contain the same particular elements as one another, but the layer 24 can have a different concentration of the particular element than the layer 22. More specifically, as discussed above, the layer 22 can comprise a first concentration of the particular element which is defined as the number of atoms per unit area of the particular element in the first layer. Similarly, the second layer can comprise a second concentration of the particular element defined as the number of atoms per unit area of the particular element in the second layer. The second concentration can be different than the first concentration, which can manifest as a difference in crystallographic properties of the second layer 24 relative to the first layer 22. Such difference in crystallographic properties, can, for example, be a difference in texture. Thus, layers 22 and 24 can comprise substantially the same composition as one another, but can have different crystallographic properties than one another due to utilization of different ALD conditions for forming layer 24 than for forming layer 22. Such different conditions can be differences in any processing condition, including, for example, differences in one or more reactor conditions such as pressure, temperature, etc. Alternatively, or additionally, the differences in ALD conditions utilized for forming layer 24 relative to layer 22 can be include a difference in the precursor utilized for formation of the second layer 24 relative to the first layer 22.

As indicated by the discussion above, FIG. 3 can be considered to illustrate two different aspects of the invention. In one aspect, layers 22 and 24 comprise substantially the same composition as one another, but differ in crystallographic properties relative to one another due to differences in ALD conditions utilized for formation of layer 24 relative to layer 22. In another aspect, layers 22 and 24 can be part of a mixed dielectric material and can have different compositions relative to one another, but can have the same crystallographic orientation as one another due to the ALD conditions utilized for forming the layers. In such aspect, layers 22 and 24 can, for example, be part of a BST material, and can have a desired perovskite crystallographic orientation induced by the ALD processing conditions utilized to form layers 22 and 24.

The second aspect can be considered to comprise atomic layer deposition of the first and second elements into a common pre-determined atomic arrangement within a material. In some aspects the first and second elements can be atomic layer deposited under different reactor ambient conditions relative to one another (for instance, one or both of the temperature and pressure within a reaction chamber can be different during the ALD of the second element than during the ALD of the first element) to achieve the common pre-determined atomic arrangement of both elements.

Referring next to FIG. 4, a third layer 26 of the crystalline dielectric material is formed over the second layer 24. The third layer 26 is formed by ALD, and can comprise a similar composition to layer 24, or can comprise a different composition. For instance, layer 26 can comprise an element identical to that in layer 24, but formed to have a different crystallographic orientation than is present in layer 24 through differences in the ALD processing utilized to form layer 26 relative to the processing utilized to form layer 24. Alternatively, layer 26 can comprise a different composition than that layer 24, but can have the same crystallographic orientation as layer 24 through utilization of appropriate ALD methodologies.

In an exemplary aspect, layers 22, 24 and 26 are together part of a multi-component perovskite material (for instance, BST or PZT). The layers 22, 24 and 26 can each correspond to a monolayer formed through ALD processing, and can each have a different composition than the other. The crystallographic orientation of the multi-component dielectric material comprising layers 22, 24 and 26 is provided through use of appropriate ALD conditions during formation of each layer, and thus the layers are in a desired perovskite crystallographic orientation, rather than in a non-desired orientation (such as, for example, a pyrochlore orientation), even though no template materials have been incorporated into the dielectric material.

Notably, the crystallographic properties of the crystalline material containing layers 22, 24 and 26 is set through utilization of appropriate ALD conditions, rather than through utilization of a particular crystalline property of the surface on which the materials are grown. This is in contrast to epitaxial methods in which surface crystallographic properties are translated into layers grown on the surface. Thus, the crystallographic properties within layers 22, 24 and 26 may be entirely different than the crystallographic properties of the surface of electrode 20, which can enable a wide variety of electrode materials to be utilized without detrimentally impacting crystallographic properties of the dielectric material formed thereon.

Occasionally it is desired to incorporate dopants into various crystalline materials. For instance, it can be desired to incorporate various metallic materials and/or halogens as dopants into BST or PZT, with exemplary metallic materials including calcium, magnesium, niobium, or any other suitable element selected from the alkaline metals, alkaline earth metals, transition metals, lanthanide metals, etc. of the periodic table. Such dopant incorporation can be accomplished through appropriate ALD processing in some aspects of the invention.

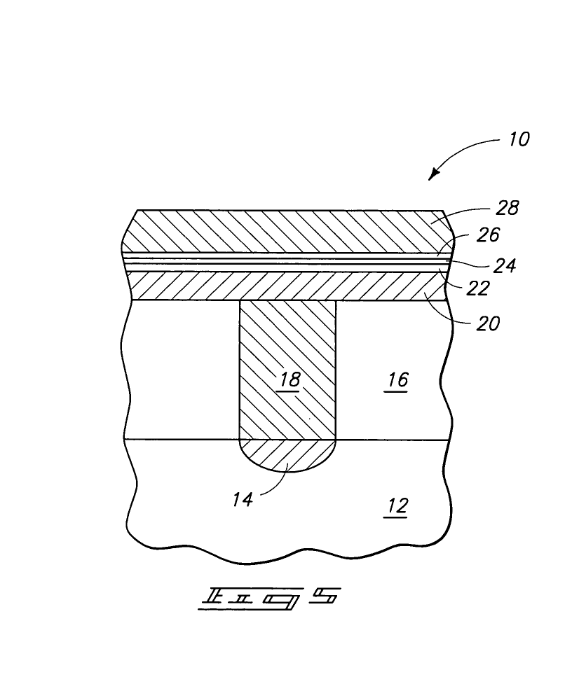

Referring to FIG. 5, a second capacitor electrode 28 is formed over dielectric material layer 26. Electrode 28 can comprise any suitable electrically conductive composition or combination of compositions. In particular aspects, layer 28 will comprise a suitable composition or combination of compositions for incorporation into a metal-insulator-metal capacitor. For instance, layer 28 can comprise, consist essentially of, or consist of platinum or other suitable noble metals. Electrode 28 is capacitively coupled to electrode 20 through the dielectric material of layers 22, 24 and 26. Thus, the electrodes 20 and 28, together with the dielectric material between the electrodes, form a capacitor construction. The capacitor construction can be electrically coupled to a transistor device through source/drain region 14, and thus can be part of a dynamic random access memory (DRAM) cell. Such cell can be part of a memory array comprising a plurality of substantially identical memory cells, and such memory array can be used in an electronic system, such as, for example, a system utilized in a personal computer, a clock, a car, an airplane, etc.

It is to be understood that the dielectric material between the capacitor electrodes would typically comprise more than the three ALD-formed monolayers that are shown. For instance, the dielectric material can be formed to a thickness of from about 10 Å to about 100 Å (or greater) through alternating ALD pulses.

The crystalline dielectric material comprising layer 22, 24 and 26 can correspond to any suitable material, and in particular aspects will comprise, consist essentially of, or consist of barium strontium titanate or lead zirconate titanate. Accordingly, the material can comprise barium, strontium, titanium and oxygen; or alternatively can comprise lead, zirconium, titanium and oxygen. In such aspects, the crystalline dielectric material containing layers 22, 24 and 26 can be substantially entirely in a non-pyrochlore phase (with the term “substantially entirely” indicating that there is no detectable pyrochlore phase within the material), and yet the formation of the dielectric material is conducted entirely without utilization of a crystallographic template. Instead, the formation of the material is conducted through utilization of appropriate ALD processing conditions to form the desired perovskite crystalline phase throughout the material.

Methodology of the present invention can be used for forming any desired crystallographic dielectric material through ALD processing, and can also be extended to formation of various conductive materials. Exemplary aspects for utilizing methodology of the present invention to form perovskite dielectric materials are as follows.

### EXAMPLE 1

### Formation of STO

Exemplary ALD methodologies for forming STO can comprise utilization of precursors including Sr(C₁₁H₁₉O₂)₂(Sr(thd)₂), Ti(OₓC₃H₇)₄, and remote flame activated H₂O; where thd is bis(2,2,6,6-tetramethyl-3,5-heptanedionate). The processing conditions can include a pressure of from about 0.4 Torr to about 1 Torr, and a temperature of from about 150° C. to about 350° C.; with 250° C. being typical. The desired perovskite crystallographic orientation throughout the STO is induced by configuration of the ligands attached to the precursors (for instance, by optimization to size and orientation for a desired crystallographic orientation). The atomic arrangement of a film formed through one or more ALD cycles can also be influenced by the temperature and pressure within a reaction chamber. In particular applications, ALD cycles providing n cycles of Sr and H₂O can be followed by m cycles providing Ti and H₂O. The number of cycles n can be one or more, and the number of cycles m can also be one or more. The relative number of cycles m to cycles n can influence surface coverage (which influences number of atoms per unit area), and thus can influence the crystal structure and the lattice structure of the ALD-formed film. Any other suitable precursors for STO can be utilized in other aspects of the invention, including, for example, Sr(tmhd)₂ (where tmhd is tetramethyl heptanedionate), strontium bis(triisopropylcyclopentadienyl) ((Sr{C₅-i-Pr₃H₂)₂), Ti(i-OPr)₄, etc.

### EXAMPLE 2

### Formation of PZT

Exemplary ALD methodologies for forming PZT can include the following. The precursors utilized can include any precursors known to be suitable for formation of PZT. The processing conditions can include any conditions known to be suitable for formation of PZT. The desired perovskite crystallographic orientation throughout the PZT is induced by configuration of the ligands attached to the precursors (for instance, by optimization to size and orientation for a desired crystallographic orientation). The atomic arrangement of a film formed through one or more ALD cycles can also be influenced by the temperature and pressure within a reaction chamber. In particular applications, ALD cycles providing n cycles of lead can be followed by m cycles providing Zr, and p cycles providing Ti. The number of cycles n can be one or more, the number of cycles m can be one or more, and the number of cycles p can also be one or more. The relative number of cycles m to cycles n and p can influence surface coverage (which influences number of atoms per unit area), and thus can influence the crystal structure and the lattice structure of the ALD-formed film.

### EXAMPLE 3

### Formation of BST

Exemplary ALD methodologies for forming BST can include the following. The precursors utilized can include any precursors known to be suitable for formation of BST. The processing conditions can include any conditions known to be suitable for formation of BST. The desired perovskite crystallographic orientation throughout the BST is induced by configuration of the ligands attached to the precursors (for instance, by optimization to size and orientation for a desired crystallographic orientation). The atomic arrangement of a film formed through one or more ALD cycles can also be influenced by the temperature and pressure within a reaction chamber. In particular applications, ALD cycles providing n cycles of Ba can be followed by m cycles providing Sr, and p cycles providing Ti. The number of cycles n can be one or more, the number of cycles m can be one or more, and the number of cycles p can also be one or more. The relative number of cycles m to cycles n and p can influence surface coverage (which influences number of atoms per unit area), and thus can influence the crystal structure and the lattice structure of the ALD-formed film.

Further aspects of the invention are described with reference to FIGS. 6-10.

Referring to FIG. 6, a pair of fragments 50 and 60 are illustrated. The fragments show an element “M” in two different lattice orientations. The orientation of fragment 50 is more densely packed, and accordingly has a higher concentration of element “M” therein than does the lattice configuration of fragment 60. Specifically, the number of atoms per unit area of element “M” in the lattice configuration of fragment 50 is higher than that in the lattice configuration of fragment 60.

In accordance with aspects of the present invention, the material “M” can be selectively deposited in either the lattice configuration of fragment 50 or the lattice configuration of fragment 60 utilizing particular ALD processing. Specifically, appropriate precursor and/or other processing parameters can be chosen to form the element “M” in the lattice configuration of fragment 50, or the suitable precursor and/or other processing parameters can be chosen to form the element “M” in the lattice configuration of fragment 60.

Although fragments 50 and 60 are shown containing only a single element, and accordingly the element is truly in elemental form in fragments 50 and 60, it is to be understood that the element can also be part of a compound. The fragments 50 and 60 diagrammatically illustrate different lattice configurations, and it is to be understood that elements can form lattice configurations other than those shown in fragments 50 and 60.

In an exemplary aspect, a titanium-containing material is formed, and the lattice configuration of the material is dictated by the precursor utilized during ALD formation of various layers of the material. The precursor can comprise, for example, titanium tetrachloride, Ti-isopropoxide, tetrakis(dimethylamino)titanium, or tetrakis(diethylamino)titanium.

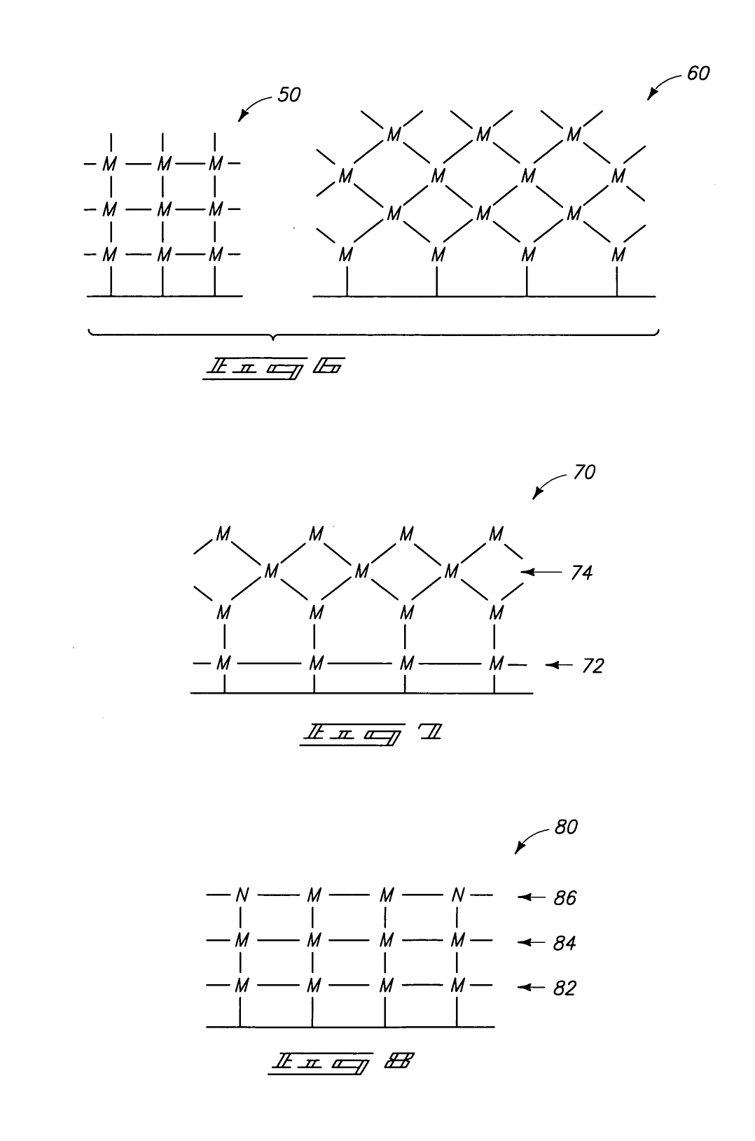

FIG. 7 illustrates an aspect of the invention in which ALD methodologies are chosen to induce a change in crystallography throughout a thickness of a material. Specifically, FIG. 7 shows a fragment 70 comprising a bottom portion 72 formed in the crystallographic orientation of the fragment 50 of FIG. 6, and an upper portion 74 formed in the crystallographic orientation of fragment 60 of FIG. 6. The upper portion is in direct contact with the bottom portion. The switch in going from the lattice configuration of the lower portion to the lattice configuration of the upper portion can be accomplished by changing ALD process conditions in forming the layers of the upper portion relative to the layers of the lower portion. For instance, the ALD precursor can be changed in forming the upper portion relative to forming the lower portion.

FIG. 8 shows a fragment 80 illustrating another aspect of the invention. Specifically, the fragment 80 has dopant “N” placed within the lattice structure that has been previously described as the lattice structure 50 of FIG. 6. The ALD conditions utilized to form the lattice of FIG. 8 can precisely form the dopant at periodic locations within a given layer, and accordingly the dopant concentration can be tightly controlled within a material formed through multiple iterations of ALD processing.

The shown fragment 80 comprises three layers (82, 84 and 86), and the dopant “N” is provided only in the uppermost layer 86. Such can be accomplished by forming uppermost layer 86 with different ALD conditions than is utilized to form lower layers 82 and 84.

Although the dopant is shown in the uppermost layer, it is to be understood that the dopant can be provided in any desired location within the ALD-formed material of fragment 80, including, for example, at the lowestmost layer, the uppermost layer, or a central location between the uppermost and lowermost layers. Further, the concentration of dopant within a given layer can be modified by altering ALD processing conditions utilized to provide the dopant. In an exemplary aspect, the dopant corresponds to niobium or fluorine, and is provided within a perovskite crystallographic lattice comprising barium, strontium, tantalum and oxygen.

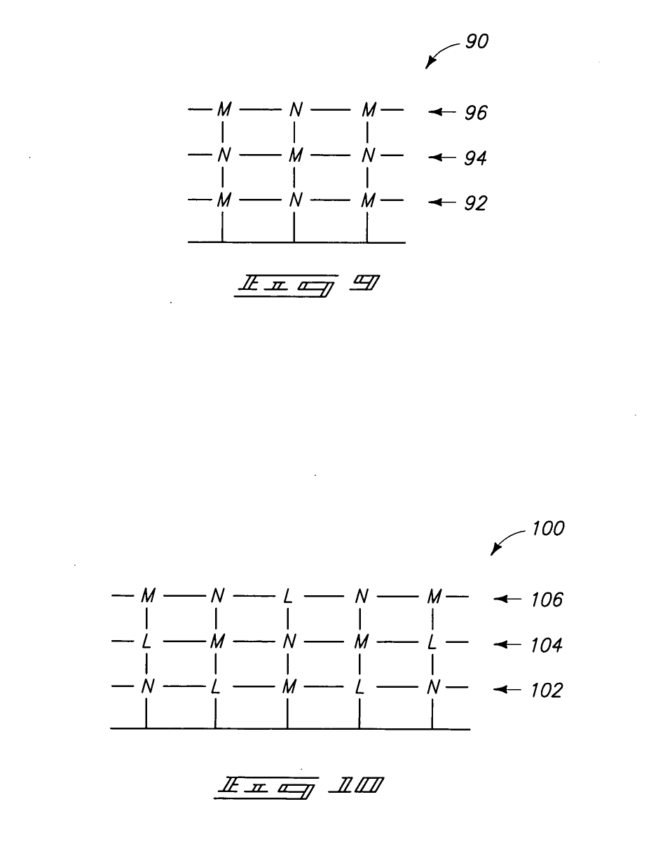

FIG. 9 shows a fragment 90 illustrating another aspect of the invention. Specifically, the fragment 90 has two different components “M” and “N” placed within a lattice structure to form alternating rows 92, 94 and 96. One of the components “M” and “N” can be a dopant, or alternatively neither of the components “M” and “N” can be a dopant The ALD conditions utilized to form the lattice of FIG. 9 can precisely form the components “M” and “N” at periodic locations within a given material, and accordingly the crystallographic orientation and lattice structure of the material containing components “M” and “N” can be tightly controlled through ALD processing.

FIG. 10 shows a fragment 100 illustrating another aspect of the invention. Specifically, the fragment 100 has three different components “L”, “M” and “N” placed within a lattice structure to form rows 102, 104 and 106. One or more of the components “L”, “M” and “N” can be a dopant, or alternatively none of the components “L”, “M” and “N” can be a dopant The ALD conditions utilized to form the lattice of FIG. 10 can precisely form the components “L”, “M” and “N” at periodic locations within a given material, and accordingly the crystallographic orientation and lattice structure of the material containing components “L”, “M” and “N” can be tightly controlled through ALD processing.

Methodology of the invention for inducing desired crystallographic properties within materials can have numerous applications. For instance, the crystallographic orientation (texture) in thin films of perovskite materials can have strong effects on properties of the films. For example, remnant polarization in ferroelectric films such as Pb, ZrₓTi₍₁₋ₓ₎O₃(PZT) can be texture-dependent, so the ability to switch domains in a PZT non-volatile memory device (NVRAM) can be strongly influenced by the texture of the PZT material.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. An atomic layer deposition (ALD) method for forming a crystalline material, comprising:
atomic layer depositing a first layer of the crystalline material; the first layer having an element contained within a pre-determined atomic arrangement; and
after depositing the first layer, atomic layer depositing a second layer of the crystalline material in direct contact with the first layer; the second layer having a second element, different from the first element, contained within the pre-determined atomic arrangement.

2. The atomic layer deposition method of claim 1 wherein the crystalline material is a dielectric material.

3. The atomic layer deposition method of claim 1 wherein the atomic layer deposition of the first layer utilizes first reactor ambient conditions, and the atomic layer deposition of the second layer utilizes second reactor ambient conditions different from the first reactor ambient conditions.

4. The atomic layer deposition method of claim 1 wherein the first and second elements are selected from the group consisting of barium, bismuth, cobalt, lanthanum, lead, magnesium, niobium, oxygen, ruthenium, strontium, titanium, tantalum and zirconium.

5. An atomic layer deposition (ALD) method for forming a crystalline material, comprising:
atomic layer depositing a first layer of the crystalline material utilizing first conditions; the first layer having an element contained within a first atomic arrangement having a first crystallographic orientation; and
after depositing the first layer, atomic layer depositing a second layer of the crystalline material in direct contact with the first layer utilizing second conditions which are different from the first conditions; the second layer having the element contained within a second atomic arrangement having a second crystallographic orientation which is different than the first crystallographic orientation.

6. The atomic layer deposition method of claim 5 wherein the crystalline material is a dielectric material.

7. The atomic layer deposition method of claim 5 wherein the difference between the first and second conditions includes at least a difference in a precursor utilized for forming the second layer relative to a precursor utilized for forming the first layer.

8. The atomic layer deposition method of claim 5 wherein the element is barium, bismuth, cobalt, lanthanum, lead, magnesium, niobium, oxygen, ruthenium, strontium, titanium, tantalum or zirconium.

9. The atomic layer deposition method of claim 5, wherein the depositing of one or both of the first and second layers includes incorporation of a dopant into the layer.

10. An atomic layer deposition (ALD) method for forming a crystalline material containing a particular element, comprising:
forming a first layer of the crystalline material with a first ALD precursor containing the particular element; the first layer having a first concentration of the particular element defined as the number of atoms per unit area of the particular element in the first layer; and
after forming the first layer, forming a second layer of the crystalline material with a second ALD precursor containing the particular element and being different from the first ALD precursor; the second layer having a second concentration of the particular element defined as the number of atoms per unit area of the particular element in the second layer; the second concentration being different than the first concentration.

11. The atomic layer deposition method of claim 10 wherein the crystalline material is a dielectric material.

12. The atomic layer deposition method of claim 10 wherein the particular element is part of a compound.

13. The atomic layer deposition method of claim 10 wherein the difference in the second concentration relative to the first concentration is manifested as a difference in crystallographic properties of the crystalline material in the second layer relative to the first layer.

14-16. (canceled)

17. The atomic layer deposition method of claim 10 wherein the forming of one or both of the first and second layers includes incorporation of a dopant into the layer.

18-37. (canceled)
